(19) United States
(12) Patent Application Publication
(10) Pub. No.: US 2009/0009935 A1
(43) Pub. Date: Jan. 8, 2009

(54) HOUSING FOR AN ELECTRONIC DEVICE AND METHOD FOR MAKING THE HOUSING

(75) Inventors: CHE-YUAN HSU, Shindian (TW); RISTO-PEKKA SALMIO, Jarvenpaa (FI); CHENG-WEN SU, Shindian (TW); GANG HUANG, Shenzhen (CN); YAN-MIN WANG, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignees: SHENZHEN FUTAIHONG PRECISION INDUSTRY CO., LTD., ShenZhen City (CN); SUTECH TRADING LIMITED, Tortola (VG)

(21) Appl. No.: 11/959,159

(22) Filed: Dec. 18, 2007

(30) Foreign Application Priority Data
Jul. 4, 2007 (CN) 200710076371.8

(51) Int. Cl. B29C 45/16; H05K 7/00

(52) U.S. Cl. 361/679; 264/241

(57) ABSTRACT

The housing (100) for an electronic device includes a transparent substrate (10) and a decorative part (20). The transparent substrate is made of a transparent moldable material. The transparent substrate includes an out portion (11) and an inner portion (12). The decorative part is received in the inner portion of the transparent substrate. The substrate is injection molded to enclose the decorative part.

### CROSS-REFERENCE TO RELATED APPLICATIONS

This application is related to a co-pending U.S. patent application Ser. No. (Attorney Docket No. US14154), entitled “HOUSING FOR AN ELECTRONIC DEVICE, ELECTRONIC DEVICE USING THE HOUSING, AND METHOD FOR MAKING THE HOUSING”, by Che-Yuan Hsu et al. This application is also related to another co-pending U.S. patent application Ser. No. (Attorney Docket Nos. US14159), entitled “HOUSING FOR ELECTRONIC DEVICES, ELECTRONIC DEVICE USING THE HOUSING AND METHOD FOR MAKING THE HOUSING”, by Che-Yuan Hsu et al. Such applications have the same assignee as the present application and have been concurrently filed herewith. The above-identified applications are incorporated herein by reference. This application claims all benefits accruing under 35 U.S.C. §119 from China Patent Application No. 200710076371.8, filed on Jul. 4, 2007 in the China Intellectual Property Office, the disclosure of which is incorporated herein by reference.

### BACKGROUND OF THE INVENTION

1. Field of the Invention

The present invention generally relates to housings, and particularly, to a housing for an electronic device, and to a method for making the housing injection molding process.

2. Discussion of the Related Art

Nowadays, metal parts are usually used to create housings for electronic devices to improve decorative appearance of the housings. However, the metal parts are typically exposed on the outer area of the housing. The metal parts are prone to be abraded or corroded to diminish metal luster during use. Furthermore, the metal parts exposed out of the housings are prone to be inducted to carry static electricity, thereby may cause failure in electrical elements received in the housings.

Therefore, an improved housing for an electronic device is desired in order to overcome the above-described shortcomings.

### SUMMARY

In one embodiment thereof, a housing for an electronic device is provided. The housing for an electronic device includes a transparent substrate and a decorative part. The transparent substrate is made of a transparent moldable material. The transparent substrate includes an outer portion and an inner portion. The decorative part is received in the inner portion of the transparent substrate. The substrate is injection molded to enclose the decorative part.

Other advantages and novel features will become more apparent from the following detailed description of preferred embodiments when taken in conjunction with the accompanying drawings.

### BRIEF DESCRIPTION OF THE DRAWINGS

Many aspects of the housing for an electronic device can be better understood with reference to the following drawing. The components in the drawing are not necessarily drawn to scale, the emphasis instead being placed upon clearly illustrating the principles of the housing for an electronic device. Moreover, in the drawing like reference numerals designate corresponding parts throughout the several views.

FIG. 1 is a cross-section view of a preferred embodiment of a housing for an electronic device;

FIG. 2 is a cross-section view of a preferred embodiment of a mold for molding the housing shown in FIG. 1;

FIG. 3 is a schematic view of a preferred embodiment of a decorative part of the housing shown in FIG. 1;

FIG. 4 is a cross-section view of the mold shown in FIG. 2 with the decorative part fixed thereon;

FIG. 5 is a cross-section view of the mold in FIG. 4 at a close state; and

FIG. 6 is a cross-section view of the mold in FIG. 4, with the housing molded therein.

### DETAILED DESCRIPTION OF THE PREFERRED EMBODIMENTS

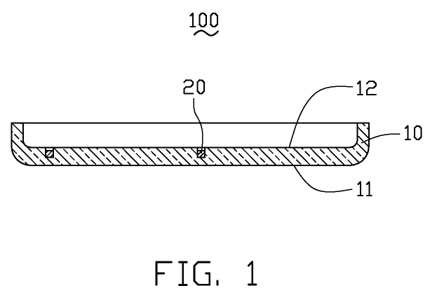

Referring to FIG. 1, in a present embodiment, a housing 100 includes a transparent substrate 10 and a decorative part 20.

The substrate 10 includes an outer portion 11 and an inner portion 12 on the opposite side to the outer portion 11. The decorative part 20 is received in the inner portion 12 of the substrate 10. The substrate 10 is made of a transparent moldable material selected from a group consisting of polycarbonate, polymethyl methacrylate, polystyrene, polyvinyl chloride, silicon gel, or any desired combination thereof. The substrate 10 is molded to enclose the decorative part 20 therein via injection molding process. The decorative part 20 is selected from a group consisting of metal, ceramic, plated articles, and glass.

During use of the housing 100, the decorative part 20 is received in the inner portion 12 of the substrate 10, thereby prevents the decorative part 20 from being abraded or corroded.

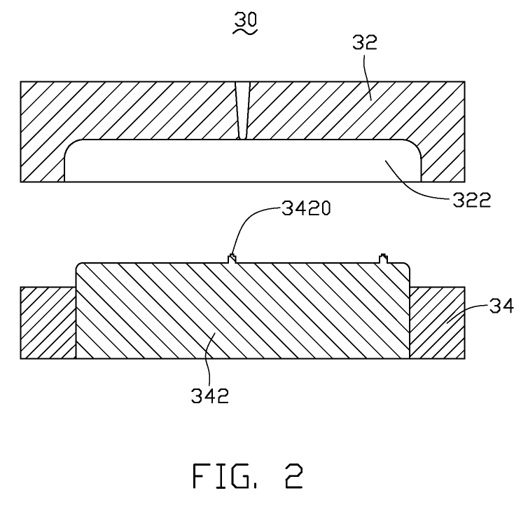

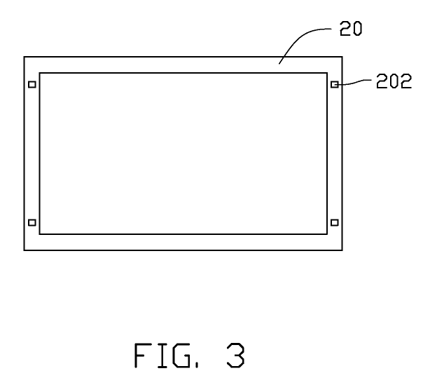

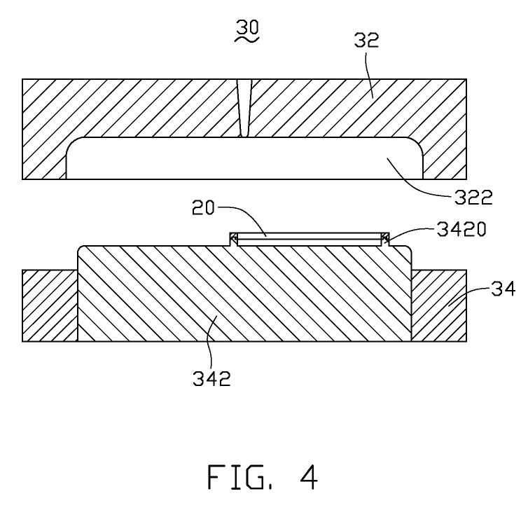

An exemplary method for making the housing 100 is provided. Firstly, referring to FIG. 2 and FIG. 3, an injection mold 30 and the decorative part 20 are provided. The mold 30 includes a female mold 32 and a male mold 34 matingly engageable with the female mold 32. The female mold 32 has a recessed portion 322 formed therein. The male mold 34 has a mold core 342 mounted thereon. The mold core 342 has a plurality of fixing poles 3420 disposed thereon for holding the decorative part 20. The decorative part 20 has a plurality of fixing holes 202 corresponding to the fixing poles 3420. Referring to FIG. 4, the decorative part 20 is fixed on the fixing poles 3420 of the mold core 342, with each of the fixing poles 3420 inserted into a respective one of the fixing holes 202.

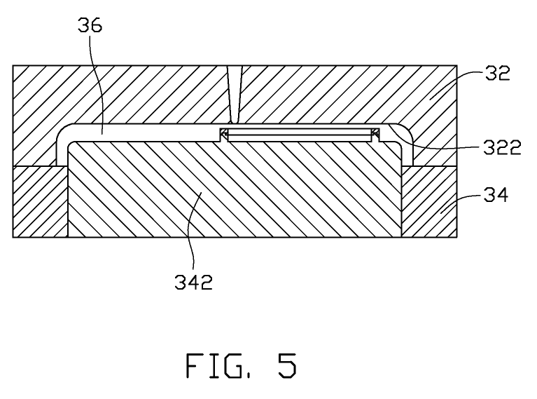

Secondly, referring to FIG. 5, the mold 30 is closed. A molding cavity 36 is defined between the female mold 32 and the male mold 34.

Thirdly, a clear molten plastic is injection molded into the molding cavity 36 to enclose the decorative part 20, thereby forming the substrate 10.

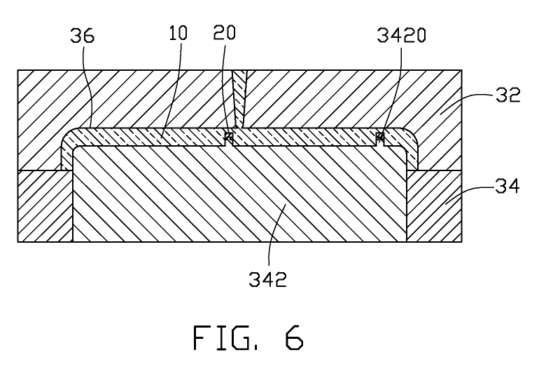

Finally, referring to FIG. 6, the substrate 10 and the decorative part 20 are integrally formed together and cooled. As a result, the housing 100 is formed and can be removed from the mold 30.

It should be understood that after the substrate 10 being formed, the mold core 342 could further be moved to compress the substrate 10 so as to reduce the stress generated between the substrate 10 and the decorative part 20. Thus, any potential image aberration caused by the birefringence of the substrate 10 can be reduced.

It should be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A housing for an electronic device, comprising:
a transparent substrate made of a transparent moldable material, the transparent substrate comprising an outer portion and an inner portion; and
a decorative part received in the inner portion of the transparent substrate, the substrate being injection molded to enclose the decorative part.

2. The housing as claimed in claim 1, wherein the substrate is made of material selected from a group consisting of polycarbonate, polymethyl methacrylate, polystyrene, polyvinyl chloride, silicon gel, and any desired combination thereof.

3. The housing as claimed in claim 1, wherein the decorative part is selected from a group consisting of metal, ceramic, plated articles, and glass.

4. A method for making a housing, comprising steps of:
providing an injection mold, the mold including a female mold and a male mold matingly engageable with the female mold, the female mold having a recessed portion formed therein, the male mold having a mold core mounted thereon;
providing a decorative part;
fixing the decorative part onto the mold core;
injection molding a molten moldable material into the mold to form a substrate enclosing the decorative part.

5. The method for making a housing as claimed in claim 4, wherein the substrate is made of material selected from a group consisting of polycarbonate, polymethyl methacrylate, polystyrene, polyvinyl chloride, silicon gel, and any desired combination thereof.

6. The method for making a housing as claimed in claim 4, wherein the decorative part is selected from a group consisting of metal, ceramic, plated articles, and glass.

7. The method for making a housing as claimed in claim 4, wherein the mold core has a plurality of fixing poles disposed thereon for holding the decorative part, the decorative part having a plurality of fixing holes corresponding to the fixing poles, the decorative part being fixed on the fixing poles of the mold core, each of the fixing poles being inserted into a respective one of the fixing holes.

8. The method for making a housing as claimed in claim 4, further comprising a step of moving the mold core to compress the substrate so as to reduce a stress generated between the substrate and the decorative part.
